(19) United States
(12) Patent Application Publication
(10) Pub. No.: US 2014/0319673 A1
(43) Pub. Date: Oct. 30, 2014

(54) SEMICONDUCTOR DEVICE

(71) Applicant: DAIKIN INDUSTRIES, LTD., Osaka-shi, Osaka (JP)

(72) Inventors: Yueqiang Zhou, Kusatsu-shi (JP); Toshiyuki Maeda, Kusatsu-shi (JP)

(21) Appl. No.: 14/356,459

(22) PCT Filed: Nov. 7, 2012
(86) PCT No.: PCT/JP2012/007146

§ 371 Date: May 6, 2014

(30) Foreign Application Priority Data
Nov. 7, 2011 (JP) 2011-243073

(51) Int. Cl. H01L 23/46

(52) U.S. Cl. CPC H01L 23/46
USPC 257/712

(57) ABSTRACT

In a semiconductor device in which a semiconductor chip is cooled by a cooler, an insulating member between a semiconductor chip and a cooler is omitted in order to simplify the configuration. A cooler (23, 24, 25) for performing heat exchange between a semiconductor chip (21, 22) and a refrigerant is provided. The refrigerant is non-conductive. The semiconductor chip (21, 22) and the cooler (23, 24, 25) are connected to each other through a conductive connection component (28) or are directly connected to each other.

### TECHNICAL FIELD

The present invention relates to semiconductor devices in which semiconductor chips are cooled by coolers.

### BACKGROUND ART

Some insulated gate bipolar transistors (IGBTs) used in, for example, inverter circuits are cooled in air-cooling or water-cooling coolers (see, for example, Patent Document 1).

These air-cooling coolers generally tend to be large. Such a large cooler has difficulty in establishing insulation between the cooler and a housing accommodating, for example, an IGBT and an inverter circuit. In a water-cooling cooler, since water has conductivity, an IGBT for use in so-called high-power applications needs electrical insulation between a semiconductor chip constituting the IGBT and a cooler. Thus, in each of the cases of employing an air-cooling cooler and of employing a water-cooling cooler, an insulating member is typically provided between a semiconductor chip and a cooler (see, for example, Patent Document 1).

### CITATION LIST

### Patent Document

PATENT DOCUMENT 1: Japanese Unexamined Patent Publication No. 2005-123233

### SUMMARY OF THE INVENTION

### Technical Problem

The presence of such an insulating member, however, increases the thermal resistance between an IGBT and a cooler to reduce the cooling efficiency, and also increases the cost for the device.

It is therefore an object of the present invention to provide a semiconductor device in which a semiconductor chip is cooled by a cooler and which can enhance the cooling efficiency without an insulating member between the semiconductor chip and the cooler so that a cooling system is simplified and a device cost is reduced.

### Solution to the Problem

To achieve the above-described object, in a first aspect, a semiconductor device includes: a semiconductor chip (21, 22); and a cooler (23, 24, 25) that performs heat exchange between the semiconductor chip (21, 22) and refrigerant, wherein the refrigerant is non-conductive, and the semiconductor chip (21, 22) and the cooler (23, 24, 25) are either connected to each other via a conductive connection component (28) or directly connected to each other.

In this configuration, refrigerant is non-conductive. Thus, even when the semiconductor chip (21, 22) and the cooler (23, 24, 25) are connected to each other via a conductive connection component (28) or directly connected to each other, no electric current flows out from the semiconductor chip (21, 22) into a source of refrigerant through the refrigerant.

In a second aspect, in the semiconductor device of the first aspect, the cooler (23, 24, 25) is used as a bus bar that conducts electric current.

With this configuration, the cooler (23, 24, 25) is also used as the bus bar.

In a third aspect, in the semiconductor device of the first or second aspect, the cooler (23, 24, 25) is connected to an electrode (E, C, . . . ) on the semiconductor chip (21, 22).

In a fourth aspect, in the semiconductor device of any one of the first through third aspects, the cooler (23, 24, 25) is located on each surface of the semiconductor chip (21, 22).

In a fifth aspect, in the semiconductor device of any one of the first through fourth aspects, the semiconductor chip (21, 22) includes a plurality of semiconductor chips (21, 22), and the plurality of semiconductor chips (21, 22) share the cooler (23, 24, 25).

In a sixth aspect, in the semiconductor device of any one of the first through fifth aspects, the refrigerant is refrigerant of a refrigerant circuit (50) that performs a refrigeration cycle, and the cooler (23, 24, 25) is connected to a piping (51) of the refrigerant circuit (50) through a non-conductive piping member (29).

In this configuration, the piping (51) of the refrigerant circuit (50) is electrically isolated from the cooler (23, 24, 25).

In a seventh aspect, in the semiconductor device of any one of the first through sixth aspects, the semiconductor chip (21, 22) is a semiconductor device using a wide bandgap semiconductor.

Since a loss of the wide bandgap semiconductor is smaller than that in a conventional device (e.g., a Si device) with the same capacity, the chip size can be reduced.

### Advantages of the Invention

In the first aspect, no electric current flows out of the semiconductor chip (21, 22) through refrigerant. Thus, in a semiconductor device in which a semiconductor chip is cooled by a cooler, an insulating member between the semiconductor chip and the cooler can be omitted, thereby simplifying the configuration of the semiconductor device. This simplified configuration can enhance the cooling efficiency of the semiconductor chip, simplify the cooling system, and reduce an increase in cost of the semiconductor device.

In the second aspect, the number of wiring members can be reduced. In addition, heat transmitted from the semiconductor chip to peripheral components can be reduced, and the peripheral components can be cooled. Since the semiconductor chip and the peripheral components are cooled by the cooler, the area in cross section of the wiring member can be reduced.

In the third aspect, the electrode on the semiconductor chip is connected to the cooler, thereby obtaining sufficient cooling when electric current flows in the electrode on the semiconductor chip to generate heat. In particular, since the electrode is configured to have a low electrical resistance, the thermal resistance of the electrode is also low. Thus, when the cooler is brought into contact with the electrode, the cooling effect is enhanced. In addition, since the electrical position of the electrode is close to a junction of the semiconductor chip, the junction can be effectively cooled in this aspect.

In the fourth aspect, the semiconductor chip (21, 22) can be efficiency cooled. In the configuration of the fourth aspect in which the cooler is provided on each surface of the semiconductor chip, no insulating layer is provided between the wiring member and the semiconductor chip (21, 22). Thus, the wiring member can be disposed closer to the semiconductor chip than in a conventional configuration. In this manner, lines of wiring can be disposed close to each other so that the inductance can be reduced, thereby enabling improvement of electric characteristics.

In the fifth aspect, the cooler (23, 24, 25) is shared by the plurality of semiconductor chips (21, 22). Thus, the size of the semiconductor device (20) can be reduced.

In the sixth aspect, even in a configuration in which the piping (51) of the refrigerant circuit (50) is conductive, no electric current flows out of the semiconductor chip (21) through the piping (51).

In the seventh aspect, the size of the device can be reduced.

### BRIEF DESCRIPTION OF THE DRAWINGS

FIG. 1 is a circuit diagram illustrating an example configuration of an electric power converter.

FIG. 2 is a top view illustrating a semiconductor device according to a first embodiment.

FIG. 3 is a sectional view of the semiconductor device of the first embodiment.

FIG. 4 illustrates an example configuration of a switching device.

FIG. 5 illustrates an example of a refrigerant circuit that performs a refrigeration cycle.

FIG. 6 is a sectional view of a semiconductor device according to a second embodiment.

### DESCRIPTION OF EMBODIMENTS

Embodiments of the present invention will be described with reference to the drawings. Note that the following description of the preferred embodiments is merely illustrative in nature, and is not intended to limit the scope, applications, and use of the invention.

### First Embodiment

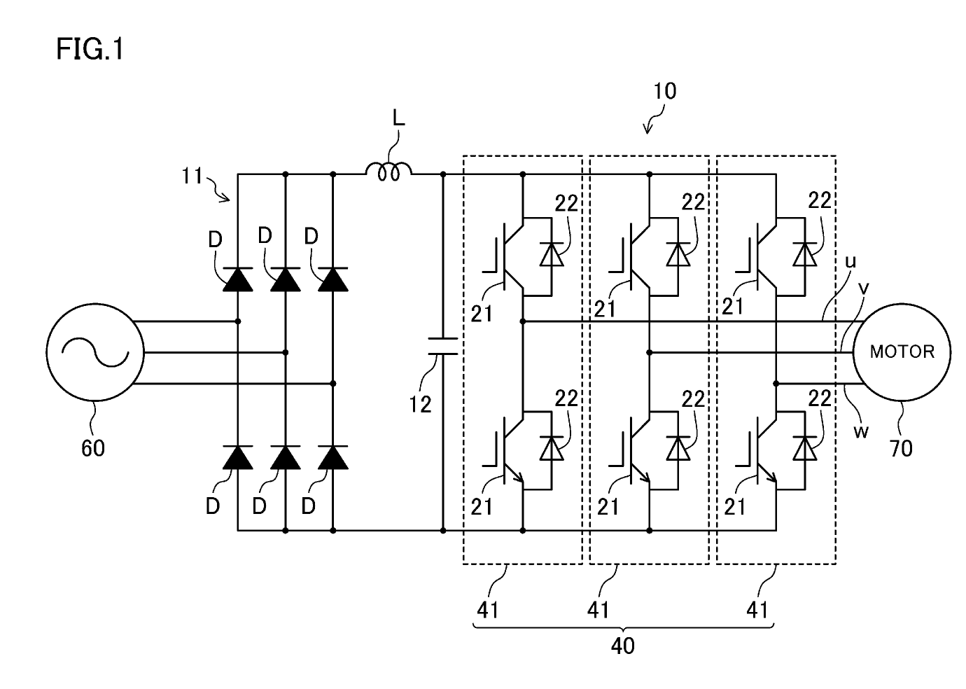

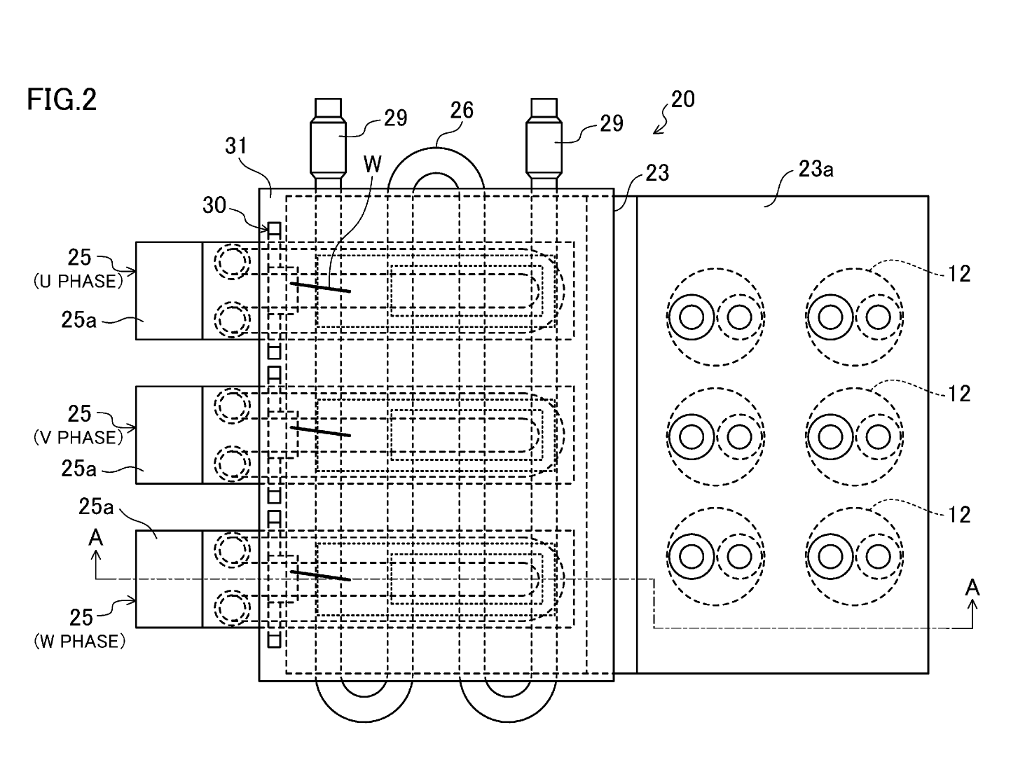

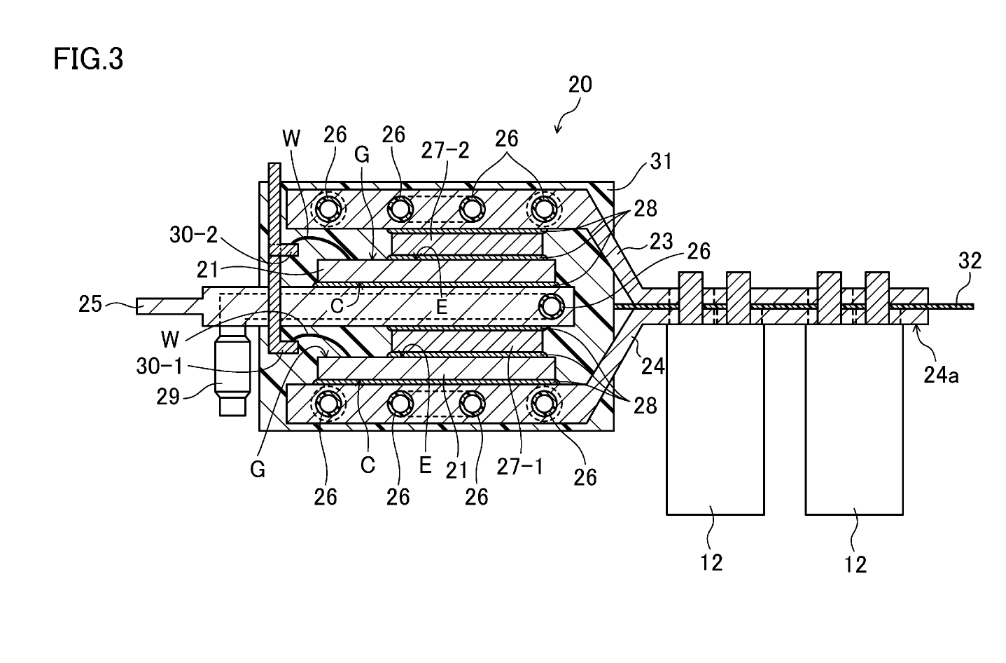

An example semiconductor device for use in an electric power converter according to an embodiment of the present invention will be described. FIG. 1 is a circuit diagram illustrating an example configuration of an electric power converter (10). FIG. 2 is a top view illustrating a semiconductor device (20) according to a first embodiment. FIG. 3 is a sectional view of the semiconductor device (20) of the first embodiment taken along line A-A in FIG. 2. FIGS. 2 and 3 also illustrate part of components constituting the electric power converter (10) in addition to the semiconductor device (20).

<Circuit Configuration of Electric Power Converter (10)>

The electric power converter (10) includes a direct-current (DC) power supply (11), a smoothing capacitor (12), and the semiconductor device (20). The DC power supply (11) includes six bridged diodes (D), and performs full-wave rectification on alternating current (AC) input from a three-phase AC power supply (60). The smoothing capacitor (12) is an electrolytic capacitor that smooths an output of the DC power supply (11), and is connected to the DC power supply (11) through a reactor (L).

<Semiconductor Device (20)>

—Circuit Configuration—

The semiconductor device (20) constitutes an inverter circuit (40) in the electric power converter (10). In the inverter circuit (40), a plurality of (six in this example) switching devices (21) are connected to each other by bridge connection. Specifically, the inverter circuit includes three switching legs (41) in each of which two switching devices (21) are connected in series. In each of the switching legs (41), midpoints of the upper-arm switching device (21) and the lower-arm switching device (21) are connected to a motor (70). Each of the switching devices (21) is connected to a freewheeling diode (22) in antiparallel with each other. An input node of the inverter circuit (40) is connected to the smoothing capacitor (12) in parallel with each other.

—Overall Configuration—

As illustrated in FIGS. 2 and 3, the semiconductor device (20) includes the switching devices (21), the freewheeling diodes (22), conduction blocks (27), control pins (30), an insulating encapsulant (31), and three types of bus bars (i.e., an N-phase bar (23), a P-phase bar (24), and output bars (25)). In this example, one N-phase bar (23), one P-phase bar (24), and three output bars (25) are provided. Each of the number of the switching devices (21), the number of the freewheeling diodes (22), and the number of the control pins (30) is six. In FIG. 3, for example, suffixes (-1, -2, . . . ) are added to reference numerals in order to identify a plurality of like components, when necessary.

As illustrated in FIG. 3, in the semiconductor device (20), the switching device (21), the conduction block (27-1), the output bar (25), the switching device (21), and the conduction block (27-2) are stacked in this order (which will be specifically described later) to constitute the switching leg (41). FIG. 3 illustrates a cross section of the W-phase switching leg (41). The other U-phase and V-phase switching legs (41) have similar structures.

Each of the U-phase, V-phase, and W-phase switching legs (41) is sandwiched between N-phase and P-phase bars (23, 24). The semiconductor device (20) is encapsulated with an insulating encapsulant (31) having an insulating property. In this manner, the semiconductor device (20) can be insulated from other components. The insulating encapsulant (31) is, for example, resin. In this encapsulation, two control pins (30) are fixed near each of the switching legs (41).

—Switching Device (21) and Freewheeling Diode (22)—

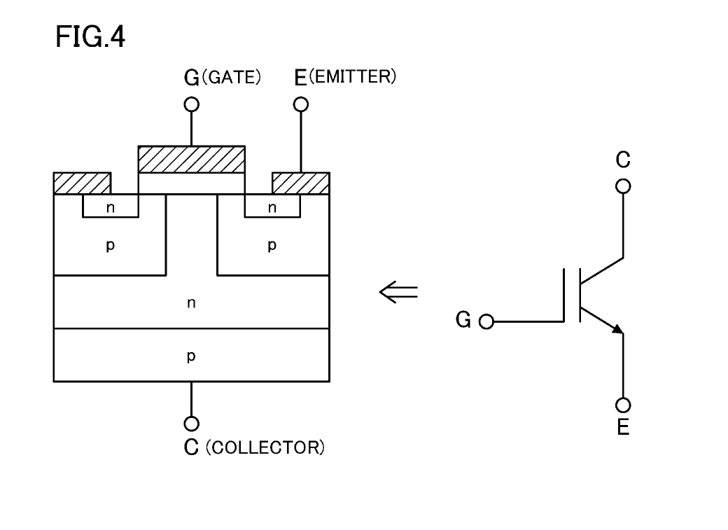

The switching devices (21) are IGBTs. FIG. 4 illustrates an example configuration of one of the switching devices (21). One switching device (21) is formed as one bare chip. As illustrated in FIG. 4, a collector (C) is formed on one surface of the bare chip, and an emitter (E) and a gate (G) are formed on the other surface. The switching devices (21) are an example of semiconductor chips according to the present invention.

One freewheeling diode (22) is formed as one bare chip. A cathode (K) is formed on one surface of the bare chip constituting the freewheeling diode (22), and an anode (A) is formed on the other surface. The freewheeling diode (22) is also an example of the semiconductor chip of the present invention.

—Bus Bar—

The bus bars (23, 24, 25) serve as wiring members for conducting electric current and also serve as coolers for cooling the switching devices (21) and the freewheeling diodes (22). As illustrated in FIGS. 2 and 3, each of the bus bars (23, 24, 25) has a plate shape. Each of the bus bars (23, 24, 25) is made of an electrically and thermally conductive material such as aluminium or copper. Electrode portions (23a, 24a, 25a) are formed at ends of the respective bus bars (23, 24, 25). As illustrated in FIGS. 2 and 3, each of the electrode portions (23a, 24a, 25a) is exposed from the insulating encapsulant (31).

A copper piping (26) is buried in each of the bus bars (23, 24, 25). As illustrated in FIG. 3, the piping (26) runs immediately under or above the switching devices (21) and the conduction blocks (27). The surface area of the piping (26) running immediately under or above the switching devices (21) and the conduction blocks (27) is selected depending on the amount of heat dissipation (which will be described later) of the switching devices (21) and the freewheeling diodes (22). In the example illustrated in FIG. 2, the piping (26) in the N-phase and P-phase bars (23, 24) meander. The piping (26) in the output bar (25) has an approximately U-shape.

Non-conductive connection piping (29) is connected to the ends of the piping (26). The connection piping (29) is made of ceramic. The connection piping (29) is an example of a non-conductive piping member of the present invention.

—Connection Between Bus Bar and Switching Device or Other Component—

In this embodiment, the vertical direction (e.g., an upper side, a lower side, an upper surface, and a lower surface) of the switching devices (21) and other components coincides with the vertical direction in FIG. 3.

As described above, three output bars (25) are provided, and one output bar (25) is connected to two switching devices (21) corresponding to one switching leg (41). Connection of each of the bus bars (23, 24, 25) to the switching device (21) and other components are similar to one another among the switching legs (41), and thus, the W-phase switching leg (41) illustrated in FIG. 3 will be described as an example.

In the example illustrated in FIG. 3, the switching device (21) located at the upper side is a lower-arm switching device, the switching device (21) located at the lower side is an upper-arm switching device, and the upper-arm switching device (21) is mounted on the P-phase bar (24). Specifically, as illustrated in FIG. 3, the collector (C) of the switching device (21) is connected to the upper surface of the P-phase bar (24) with solder (28). In this manner, the use of the solder (28) enables the collector (C) and the P-phase bar (24) to be electrically and thermally connected together. The solder (28) is an example of a connection component of the present invention.

The emitter (E) of the upper-arm switching device (21) is connected to the lower surface of the conduction block (27-1) with solder (28). The upper surface of the conduction block (27-1) is connected to the lower surface of the output bar (25) with solder (28). In this manner, the emitter (E) of the upper-arm switching device (21) is electrically and thermally connected to the output bar (25) through the conduction block (27-1). The gate (G) of the upper-arm switching device (21) is connected to the neighboring control pin (30-1) via wiring (W).

The collector (C) of the lower-arm switching device (21) is connected to the upper surface of the output bar (25) with solder (28). The emitter (E) of the lower-arm switching device (21) is connected to the lower surface of the conduction block (27-2) with solder (28). The gate (G) of the lower-arm switching device (21) is connected to the neighboring control pin (30-2) through wiring (W). The upper surface of the conduction block (27-2) is connected to the lower surface of the N-phase bar (23) with solder (28).

Although not shown in, for example, FIG. 3, each of the freewheeling diodes (22) is arranged side by side with an associated one of the switching devices (21), and is electrically and thermally connected to the N-phase and P-phase bars (23, 24), in a manner similar to the switching device (21). For example, the cathode (K) of the upper-arm freewheeling diode (22) is connected to the upper surface of the P-phase bar (24) with solder (28), and the anode (A) thereof is connected to the lower surface of the conduction block (27-1) with solder (28).

The electrode portions (23a, 24a) of the N-phase and P-phase bars (23, 24) have plate shapes as illustrated in FIGS. 2 and 3, and face each other with an insulator (32) sandwiched therebetween. Terminals (e.g., through holes) are provided in the electrode portions (23a, 24a) and are connected to the smoothing capacitor (12). The electrode portion (25a) of the output bar (25) serves as an output terminal of the inverter circuit (40). As illustrated in FIGS. 2 and 3, each of the electrode portions (23a, 24a, 25a) is exposed from the insulating encapsulant (31).

—Connection to Refrigerant Circuit (50)—

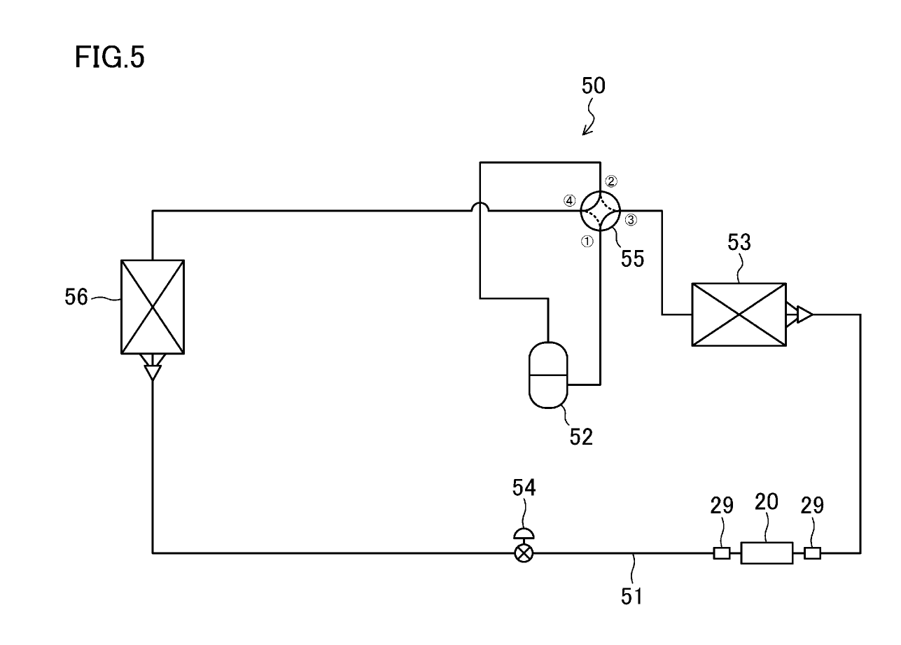

The piping (26) of each of the bus bars (23, 24, 25) is connected to a refrigerant circuit (50) that performs a refrigeration cycle, through the connection piping (29) such that refrigerant is distributed therein. FIG. 5 illustrates an example of the refrigerant circuit (50) that performs a refrigeration cycle. The refrigerant circuit (50) includes a compressor (52), an outdoor heat exchanger (53), an expansion valve (54), a four-way valve (55), and an indoor heat exchanger (56), which are connected together with a piping (51). In the refrigerant circuit (50), refrigerant circulates so that a vapor compression refrigeration cycle is performed. Refrigerant used in the refrigerant circuit (50) is non-conductive.

The indoor heat exchanger (56) is a cross-fin-and-tube heat exchanger, and performs heat exchange between refrigerant and outdoor air. As the compressor (52), various types of compressors such as a scroll compressor may be employed. The outdoor heat exchanger (53) is a cross-fin-and-tube heat exchanger, and performs heat exchange between refrigerant and outdoor air. The expansion valve (54) is connected to the outdoor heat exchanger (53) and the indoor heat exchanger (56), expands inflow refrigerant so that the pressure of the refrigerant is reduced to a predetermined pressure and then causes the resulting refrigerant to flow out. In this example, the expansion valve (54) is an electronic expansion valve with a variable opening degree. The four-way valve (55) has four ports of first through fourth ports. The four-way valve (55) can be switched between a first position (indicated by the continuous line in FIG. 1) in which the first port communicates with the third port and the second port communicates with the fourth port and a second position (indicated by the broken line in FIG. 1) in which the first port communicates with the fourth port and the second port communicates with the third port. The first port of the four-way valve (55) is connected to a discharge port of the compressor (52), and the second port of the four-way valve (55) is connected to a suction port of the compressor (52). The third port is connected to an end of the indoor heat exchanger (56) through the outdoor heat exchanger (53) and the expansion valve (54), and the fourth port is connected to the other end of the indoor heat exchanger (56). When the refrigerant circuit (50) performs cooling operation, the four-way valve (55) is switched to the first position. When the refrigerant circuit (50) performs heating operation, the four-way valve (55) is switched to the second position.

In this example, the piping (26) of each of the bus bars (23, 24, 25) is connected between the outdoor heat exchanger (53) and the expansion valve (54) such that refrigerant circulates.

<Cooling of Switching Device (21) and Freewheeling Diode (22)>

Since each of the terminals of the switching devices (21) and the freewheeling diodes (22) is electrically connected to any one of the bus bars (23, 24, 25) with the solder (28), electric current flows in the bus bars (23, 24, 25) depending on switching of the switching devices (21). In this switching, the switching devices (21) and the freewheeling diodes (22) generate heat.

On the other hand, when the refrigerant circuit (50) performs a refrigeration cycle, refrigerant is distributed in each of the bus bars (23, 24, 25). Since each of the switching devices (21) and the freewheeling diodes (22) is thermally connected to any one of the bus bars (23, 24, 25) with the solder (28), the switching devices (21) and the freewheeling diodes (22) dissipate heat to the refrigerant and are cooled in the bus bars (23, 24, 25) connected to the switching devices (21) and the freewheeling diodes (22). In this example, the N-phase bar (23) and the P-phase bar (24) are commonly used for cooling the U-phase, V-phase, and W-phase switching devices (21). Each of the output bars (25) is commonly used for cooling the switching devices (21) in the switching legs (41). That is, a plurality of semiconductor chips shares one cooler.

As described above, electric current flows in the bus bars (23, 24, 25) depending on switching of the switching devices (21). However, since the bus bars (23, 24, 25) are connected to the piping (51) of the refrigerant circuit (50) through the non-conductive connection piping (29), the piping (26) of the bus bars (23, 24, 25) is electrically insulated from the piping (51) of the refrigerant circuit (50).

For example, if refrigerant were conductive, the bus bars (23, 24, 25) would be electrically connected to the refrigerant circuit (50) even with the use of the non-conductive piping (51). On the other hand, in this embodiment, since the refrigerant is also non-conductive, the bus bars (23, 24, 25) are not electrically connected to the refrigerant circuit (50) through refrigerant. Thus, in this embodiment, electrical isolation is obtained between the semiconductor device (20) and the refrigerant circuit (50).

### Advantages of Embodiment

As described above, in this embodiment, electrical isolation is obtained between the semiconductor device (20) and the refrigerant circuit (50) without the presence of an insulating member between the cooler (the bus bars (23, 24, 25)) and the semiconductor chip (e.g., the switching devices (21)). Thus, in a semiconductor device in which a semiconductor chip is cooled by a cooler, an insulating member between the semiconductor chip and the cooler can be omitted, thereby simplifying the configuration of the semiconductor device. This configuration can enhance the cooling efficiency of the semiconductor chip, simplify the cooling system, and reduce an increase in cost of the semiconductor device. In addition, it is also possible to prevent noise generated by switching of the switching devices (21) from leaking out of the semiconductor devices (20).

Further, since the electrode portion (24a) of the P-phase bar (24) faces the electrode portion (23a) of the N-phase bar (23), the impedance of the N-phase and P-phase bars (23, 24) can be reduced.

Moreover, since the semiconductor chip is directly connected to the P-phase bar (24) and the N-phase bar (23), the joint area between the semiconductor chip and the bus bar can be increased so that the wiring impedance between the semiconductor chip and the bus bars can be reduced. In this manner, a surge voltage on the semiconductor chip can be reduced, thereby increasing the switching speed.

### Second Embodiment

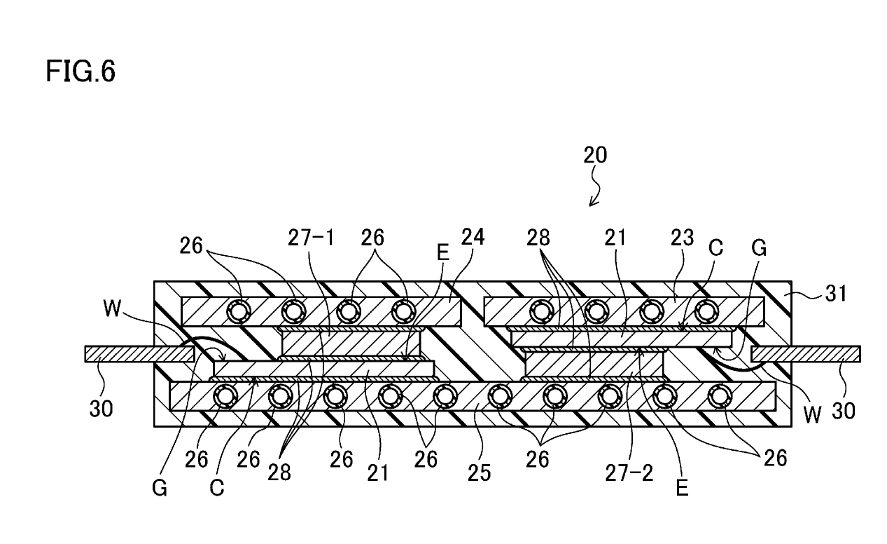

FIG. 6 is a sectional view of a semiconductor device (20) according to a second embodiment. The semiconductor device (20) of the second embodiment is different from that of the first embodiment in the structure of the switching legs (41). In the second embodiment, the vertical direction (e.g., an upper side, a lower side, an upper surface, and a lower surface) of switching devices (21) and other components coincides with the vertical direction in FIG. 6.

<Configuration of Semiconductor Device (20)>

FIG. 6 illustrates a W-phase switching leg (41). The other U-phase and V-phase switching legs (41) have similar configurations. In this semiconductor device (20), three output bars (25), one N-phase bar (23), and one P-phase bar (24) are also provided. In the example illustrated in FIG. 6, the switching device (21) located at the left in FIG. 6 is an upper-arm switching device, and the switching device (21) located at the right in FIG. 6 is a lower-arm switching device. Connection of each of the bus bars (23, 24, 25) to the switching device (21) and other components are similar to one another among the switching legs (41), and thus, the W-phase switching leg (41) illustrated in FIG. 6 will be described as an example.

As illustrated in FIG. 6, in the switching leg (41) of this embodiment, the surface of the upper-arm switching device (21) provided with a collector (C) is connected to the upper surface of the output bar (25) with solder (28). An emitter (E) of the upper-arm switching device (21) is connected to a conduction block (27-1) with solder (28).

The upper surface of the conduction block (27-1) is connected to the P-phase bar (24) with solder (28). In this manner, the emitter (E) of the upper-arm switching device (21) is electrically and thermally connected to the P-phase bar (24).

A conduction block (27-2) is mounted on the upper surface of the output bar (25), and is disposed side by side with the upper-arm switching device (21). The output bar (25) and the conduction block (27-2) are connected to each other with solder (28). The emitter (E) of the lower-arm switching device (21) is connected to the upper surface of the conduction block (27-2) with solder (28). A collector (C) of the lower-arm switching device (21) is connected to the N-phase bar (23) with solder (28).

A copper piping (26) is buried in each of the bus bars (23, 24, 25). As illustrated in FIG. 6, the piping (26) runs immediately under or above the switching devices (21) and the conduction blocks (27). The surface area of the piping (26) running immediately under or above the switching devices (21) and the conduction blocks (27) is selected depending on the amount of heat dissipation (which will be described later) of the switching devices (21) and freewheeling diodes (22). Both ends of the piping (26) is connected to a non-conductive connection piping (29).

The semiconductor device (20) is encapsulated with an insulating encapsulant (31) having an insulating property. In this manner, the semiconductor device (20) is insulated from other components. The insulating encapsulant (31) is, for example, resin. In this encapsulation, control pins (30) are fixed near each of the switching legs (41). The gate (G) of each of the switching devices (21) is connected to its neighboring one of the control pins (30) via wiring (W). The piping (26) of each of the bus bars (23, 24, 25) is connected to the piping (51) of the refrigerant circuit (50) through the connection piping (29) so that the refrigerant circulates in the piping (26).

### Advantages of Embodiment

In the second embodiment, each of the terminals of the switching devices (21) and the freewheeling diodes (22) is also electrically connected to any one of the bus bars (23, 24, 25) with the solder (28), electric current flows in the bus bars (23, 24, 25) depending on switching of the switching devices (21).

In addition, each of the switching devices (21) and the freewheeling diodes (22) is thermally connected to any one of the bus bars (23, 24, 25) with the solder (28). Thus, the switching devices (21) and the freewheeling diodes (22) dissipate heat to the refrigerant and are cooled in the bus bars (23, 24, 25) connected to the switching devices (21) and the freewheeling diodes (22).

Thus, in the second embodiment, advantages similar to those of the first embodiment can be obtained.

### Other Embodiments

Refrigerant does not need to flow in all the bus bars (23, 24, 25). Selection of one of the bus bars (23, 24, 25) in which refrigerant is to flow can be based on the amount of heat dissipation from, for example, the switching devices (21).

The freewheeling diodes (22) may be disposed outside the semiconductor device (20).

The piping (26) may be connected in series. Then, there is one pair of an inlet and an outlet of refrigerant, and thus, connection is easily achieved.

Part of the piping (26) may be exposed from the bus bars (23, 24, 25) for detection of the temperature. Such a configuration enables a temperature control of refrigerant.

The IGBTs employed as the switching devices (21) are an example. Alternatively, the switching devices (21) may be FETs, for example.

For example, the switching devices (21) are preferably semiconductor devices using a wide bandgap semiconductor (hereinafter referred to as wide bandgap semiconductor devices). Examples of the wide bandgap semiconductor include silicon carbide (SiC).

The use of the wide bandgap semiconductor devices can reduce the device size. That is, a wide bandgap semiconductor device (e.g., a SiC device) has a smaller loss than a conventional device (e.g., a Si device), and thus, the chip size can be reduced as compared to a conventional device with the same capacity.

However, since the cross sectional area of wiring (a bus bar) is generally determined depending on the value of electric current, a wide bandgap semiconductor device such as a SiC device also needs wiring of a size (in cross section) appropriate for the electric current. Consequently, it is still difficult for a conventional device to reduce the size as a whole even by simply using a wide bandgap semiconductor device. On the other hand, this embodiment uses the coolers (23, 24, 25) as bus bars, and thus, the size of the bus bars can be reduced. As a result, the device size can be reduced as a whole.

The use of the wide bandgap semiconductor device enables peripheral components to be used at low temperatures. A wide bandgap semiconductor device can be used at high temperatures (e.g., 400° C. or higher). However, peripheral components such as capacitors are used at temperatures (e.g., about 100° C.) lower than that of the wide bandgap semiconductor device. Thus, to connect the wide bandgap semiconductor device to peripheral components with a conventional copper bus bar, the peripheral components need to be disposed away from the wide bandgap semiconductor device or the temperature at which the device is used needs to be reduced. In such cases, advantages of the wide bandgap semiconductor device cannot be fully achieved.

On the other hand, in this embodiment, the bus bars (23, 24, 25) are cooed by refrigerant, and thus, the temperature of the semiconductor chips (21, 22) (semiconductor devices) are not readily transmitted to peripheral components. For this reason, the wide bandgap semiconductor device can be used at high temperatures. In addition, a capacitor and other components can be cooled advantageously, thereby a longer lifetime of the device can be achieved.

The use of the wide bandgap semiconductor device also achieves size reduction of the device with a reduced thermal resistance of the device. The wide bandgap semiconductor device has a thermal conductivity higher than (i.e., has a thermal resistance lower than) that of a conventional device (e.g., a Si device). Thus, the proportion of the thermal resistance of the insulating layer (an insulating member between a cooler and a semiconductor chip) in the total thermal resistance is large. In this embodiment, the absence of an insulating layer can achieve a smaller device with a reduced thermal resistance of the entire device.

### INDUSTRIAL APPLICABILITY

The present invention is useful for a semiconductor device in which a semiconductor chip is cooled by a cooler.

### DESCRIPTION OF REFERENCE CHARACTERS

20 semiconductor device
21 switching device (semiconductor chip)
22 freewheeling diode (semiconductor chip)
23 N-phase bar (cooler)
24 P-phase bar (cooler)
25 output bar (cooler)
28 solder (connection component)
29 connection pipe (piping member)
50 refrigerant circuit
51 pipe

1. A semiconductor device comprising:
a semiconductor chip (21, 22); and
a cooler (23, 24, 25) that performs heat exchange between the semiconductor chip (21, 22) and refrigerant, wherein
the refrigerant is non-conductive, and
the semiconductor chip (21, 22) and the cooler (23, 24, 25) are either connected to each other via a conductive connection component (28) or directly connected to each other.

2. The semiconductor device of claim 1, wherein
the cooler (23, 24, 25) is used as a bus bar that conducts electric current.

3. The semiconductor device of claim 1, wherein
the cooler (23, 24, 25) is connected to an electrode (E, C, . . . ) on the semiconductor chip (21, 22).

4. The semiconductor device of claim 1, wherein
the cooler (23, 24, 25) is located on each surface of the semiconductor chip (21, 22).

5. The semiconductor device of claim 1, wherein
the semiconductor chip (21, 22) comprises a plurality of semiconductor chips (21, 22), and
the plurality of semiconductor chips (21, 22) share the cooler (23, 24, 25).

6. The semiconductor device of claim 1, wherein
the refrigerant is refrigerant of a refrigerant circuit (50) that performs a refrigeration cycle, and
the cooler (23, 24, 25) is connected to a piping (51) of the refrigerant circuit (50) through a non-conductive piping member (29).

7. The semiconductor device of claim 1, wherein
the semiconductor chip (21, 22) is a semiconductor device using a wide bandgap semiconductor.
